(19) United States
(12) Patent Application Publication
(10) Pub. No.: US 2025/0290773 A1
(43) Pub. Date: Sep. 18, 2025

(54) METHOD AND DEVICE FOR COMPENSATING FOR AN INTERFERENCE SIGNAL

(71) Applicant: Robert Bosch GmbH, Stuttgart (DE)

(72) Inventor: Alexander Buhmann, Reutlingen (DE)

(21) Appl. No.: 19/068,313

(22) Filed: Mar. 3, 2025

(30) Foreign Application Priority Data
Mar. 13, 2024 (DE) 10 2024 202 355.8

(51) Int. Cl. G01D 3/036

(52) U.S. Cl. CPC G01D 3/036

(57) ABSTRACT

Method for compensating for an interference signal in a sensor. The method includes: sampling a sensor signal from the sensor at a first sampling frequency to generate a sampled sensor signal; providing a sampled first interference signal, which is sampled at the first sampling frequency and then upsampled to a second sampling frequency, wherein the second sampling frequency is higher than the first sampling frequency, and/or providing a sampled second interference signal, wherein the interference signal is sampled at the second sampling frequency; upsampling the sensor signal sampled at the first sampling frequency to the second sampling frequency to generate an upsampled sensor signal; and filtering the provided sampled interference signals via an adaptive filter unit to generate a filtered output signal with a compensated interference signal, wherein the upsampled sensor signal is applied as a reference signal to a reference signal input of the adaptive filter unit.

### CROSS REFERENCE

The present application claims the benefit under 35 U.S.C. § 119 of German Patent Application No. DE 10 2024 202 355.8 filed on Mar. 13, 2024, which is expressly incorporated herein by reference in its entirety.

### FIELD

The present invention relates to a method and a device for compensating for interference signals in a sensor, in particular in a micromechanical sensor.

### BACKGROUND INFORMATION

Sensors do not only measure a measurement signal, but they are also always disturbed by external unknown or known signals, hereinafter referred to as interference signals. Micromechanical sensors are widely used (but not only MEMS) and can sense a wide variety of physical quantities. U.S. Patent Application Publication No. US 2020/01456660 A1 describes a MEMS sensor with built-in self-test.

Possible external signals or disturbances include, for example, external vibrations that generate a signal in the frequency band of interest, or also stress due to temperature fluctuations, stress due to humidity, EMC disturbances, disturbances in the supply voltage. In all of these cases, the sensor delivers a sensor output signal that does not correspond to the desired measurement signal.

Various conventional methods either reduce the known interference signal or even completely compensate for it. A conventional application is, for example, acoustic noise suppression in the aviation sector, in which ambient noise from the aircraft is suppressed from the pilot's microphone recordings using an adaptive filter.

However, this conventional approach is only feasible for linear unknown filters, e.g., LTI (Linear Time Invariant) filtering. The method cannot be used in case of signal convolution or nonlinear signal distortion.

Another conventional approach is to decouple the sensor from the interference signals. This is done, for example, by using complex damper packages or special PCB designs. Alternatively, the disturbance of the sensor output signal can be accepted in the application, but this usually leads to a poorer customer experience.

### SUMMARY

The present invention provides a method for compensating for an interference signal in a sensor.

An example embodiment of the present invention provides a method for compensating for an interference signal in a sensor, comprising the steps of:
sampling a sensor signal received from the sensor at a first sampling frequency to generate a sampled sensor signal;
providing a sampled first interference signal, wherein the interference signal is sampled for this purpose at the first sampling frequency and then upsampled to a second sampling frequency, wherein the second sampling frequency is higher than the first sampling frequency, and/or providing a sampled second interference signal, wherein the interference signal is sampled for this purpose at the second higher sampling frequency;
upsampling the sensor signal sampled at the first sampling frequency to the second sampling frequency to generate an upsampled sensor signal;
filtering the provided sampled interference signals via an adaptive filter unit to generate a filtered output signal with a compensated interference signal, wherein the upsampled sensor signal is applied as a reference signal to a reference signal input of the adaptive filter unit.

In a first example embodiment of the method of the present invention, the interference signals are already present in sampled form. In this embodiment, the sampled interference signals are preferably read out from a data memory.

In a second alternative embodiment of the method of the present invention, the interference signals are sampled and processed during ongoing operation of the sensor.

In one possible example embodiment of the method of the present invention for compensating for an interference signal in a sensor, the following steps can be carried out:
sampling a sensor signal received from the sensor at a first sampling frequency to generate a sampled sensor signal;
sampling the interference signal at the first sampling frequency to generate a sampled first interference signal;
sampling the interference signal at a second sampling frequency to generate a sampled second interference signal, wherein the second sampling frequency is higher than the first sampling frequency;
upsampling the sensor signal sampled at the first sampling frequency to the second sampling frequency;
upsampling the sampled first interference signal to the second sampling frequency;
filtering the first interference signal upsampled to the second sampling frequency and the second interference signal sampled at the second sampling frequency, via an adaptive filter unit, to generate a filtered output signal with a compensated interference signal, wherein the upsampled sensor signal is applied as a reference signal to a reference signal input of the adaptive filter unit.

The above steps can also be carried out in a different order and sometimes temporally in parallel with one another.

A basic feature of the method according to the present invention is to extend conventional filters to include the function of compensating for sampled interference signals.

The method for compensating for interference signals is also able to compensate for broadband convolved interference signals.

In one possible example embodiment of the method according to the present invention for compensating for an interference signal in a sensor, the sensor signal is generated by a micromechanical sensor.

Micromechanical sensors are widely used and require little space, for example on a circuit board.

In one possible example embodiment of the method according to the present invention for compensating for an interference signal in a sensor, the output signal of the adaptive filter is subtracted from a reference signal to generate the error signal.

In one possible embodiment of the method according to the present invention for compensating for an interference signal in a sensor, the reference signal is formed by the sampled sensor signal.

In one possible embodiment of the method according to the present invention for compensating for an interference signal in a sensor, filter coefficients of the adaptive filter are iteratively adjusted to minimize an error signal.

In this case, the step size can be adapted for different application cases.

In one possible embodiment of the method according to the present invention for compensating for an interference signal in a sensor, the filter coefficients of the adaptive filter are adjusted by an adjustment algorithm.

This allows the use of different adjustment algorithms for different applications. In one possible implementation, a suitable adjustment algorithm can also be selected.

In one possible embodiment of the method according to the present invention for compensating for an interference signal in a sensor, the adjustment algorithm comprises an LMS algorithm, an RLS algorithm or an NLMS algorithm.

In one possible embodiment of the method according to the present invention for compensating for an interference signal in a sensor, wherein the filter coefficients of the adaptive filter are adjusted by an artificial neural network. The artificial neural network can be trained in advance or in the field.

In one possible embodiment of the method according to the present invention for compensating for an interference signal in a sensor, wherein the second sampling frequency is more than twice the maximum frequency of the interference signal frequency bandwidth.

In one possible embodiment of the method according to the present invention for compensating for an interference signal in a sensor, the first sampling frequency is more than twice the maximum frequency of the sensor signal frequency bandwidth.

In one possible embodiment of the method according to the present invention for compensating for an interference signal in a sensor, the interference signal is sampled at intermediate sampling frequencies to generate sampled further interference signals, wherein the further intermediate sampling frequencies lie between the first sampling frequency and the second sampling frequency. It is particularly advantageous if the intermediate sampling frequencies are a multiple of the first sampling frequency.

This allows additional support signals to be generated, which increase the compensation accuracy.

In one possible embodiment of the method according to the present invention for compensating for an interference signal in a sensor, the further interference signals sampled at the intermediate sampling frequencies are filtered together with the first interference signal upsampled to the second sampling frequency and with the second interference signal sampled at the second sampling frequency, via an adaptive filter, to generate a filtered output signal with a compensated interference signal.

In one possible embodiment of the method according to the present invention for compensating for an interference signal in a sensor, the interference signal is compensated by means of a nonlinear and/or a time-variant convolution.

According to a second aspect, the present invention provides a device for compensating for an interference signal in a sensor, comprising:
a sampling unit designed to sample a sensor signal received from the sensor at a first sampling frequency (fA1) to generate a sampled sensor signal;
a provision unit for providing a first sampled interference signal, wherein the interference signal is sampled for this purpose at the first sampling frequency and then upsampled to a second sampling frequency, wherein the second sampling frequency is higher than the first sampling frequency, and/or for providing a sampled second interference signal, wherein the interference signal is sampled for this purpose at the second higher sampling frequency;
a further sampling unit which is designed to upsample the sensor signal sampled at the first sampling frequency to the second sampling frequency to generate an upsampled sensor signal; and comprising
an adaptive filter unit which filters the provided first interference signal upsampled to the second sampling frequency and the provided second interference signal sampled at the second sampling frequency, to generate a filtered output signal with a compensated interference signal,
wherein the sensor signal upsampled by the further sampling unit is applied as a reference signal to a reference signal input of the adaptive filter unit of the device.

In one possible embodiment of the device of the present invention for compensating for an interference signal in a sensor, the provision unit for providing the first sampled interference signal and/or for providing the sampled second interference signal comprises:
a sampling unit designed to sample the interference signal at the first sampling frequency to generate a sampled first interference signal;
a sampling unit designed to sample the interference signal at a second sampling frequency (to generate a sampled second interference signal, wherein the second sampling frequency is higher than the first sampling frequency; and
a sampling unit designed to upsample the sampled first interference signal to the second sampling frequency.

In a further possible example embodiment of the device of the present invention for compensating for an interference signal in a sensor, the provision unit for providing the first sampled interference signal and/or the sampled second interference signal has a data memory in which the first sampled interference signal and/or the sampled second interference signal are stored.

In one possible example embodiment of the device of the present invention for compensating for an interference signal in a sensor, the filter unit contains an adaptive filter with filter coefficients that can be iteratively adjusted by an adjustment unit of the filter unit to minimize an error signal.

In one possible example embodiment of the device of the present invention for compensating for an interference signal in a sensor, the adjustment unit of the filter unit executes an adjustment algorithm, in particular an LMS algorithm, an RLS algorithm or an NLMS algorithm.

In one possible example embodiment of the device of the present invention for compensating for an interference signal in a sensor, the adjustment unit of the filter unit has an artificial neural network.

In one possible example embodiment of the device of the present invention for compensating for an interference signal in a sensor, the device contains a subtraction unit which subtracts the output signal of the adaptive filter of the filter unit from a reference signal applied to a reference signal input of the filter unit to generate the error signal.

In one possible example embodiment of the device of the present invention for compensating for an interference signal in a sensor, the sensor comprises a micromechanical sensor.

In one possible example embodiment of the device of the present invention for compensating for an interference signal in a sensor, the micromechanical sensor has a rotation rate sensor, an acceleration sensor and/or a pressure sensor.

The device according to the present invention can also be used with other sensors for compensating for an interference signal, for example with magnetic field sensors, mass flow sensors or with micromirrors, in particular with micromirrors that form part of a position closed-loop control system.

In one possible example embodiment of the device of the present invention for compensating for an interference signal in a sensor, the interference signal comprises a vibration disturbance.

The present invention further provides an apparatus comprising at least one sensor and comprising a compensation device for compensating for an interference signal in the sensor according to the second aspect of the present invention.

Preferred embodiments of the method according to the present invention will be described below with reference to the figures.

### BRIEF DESCRIPTION OF THE DRAWINGS

FIG. 1 is a flow chart of a possible example embodiment of a method according to the present invention for compensating for an interference signal in a sensor.

FIG. 2 is a block diagram showing a possible example embodiment of a device according to the present invention for compensating for an interference signal in a sensor.

FIG. 3 is a schematic view of an example embodiment of a filter unit according to the present invention which can be used in the device according to the present invention for compensating for an interference signal in a sensor.

FIG. 4 is a block diagram showing a possible example embodiment of an apparatus which contains a device for compensating for an interference signal in a sensor, according to the present invention.

FIG. 5 shows a setup to explain the functioning of the method according to an example embodiment of the present invention.

FIG. 6 shows a possible implementation of a filter unit with an artificial neural network as an adjustment unit, which can be used in the device according to the present invention for compensating for an interference signal in a sensor.

### DETAILED DESCRIPTION OF EXAMPLE EMBODIMENTS

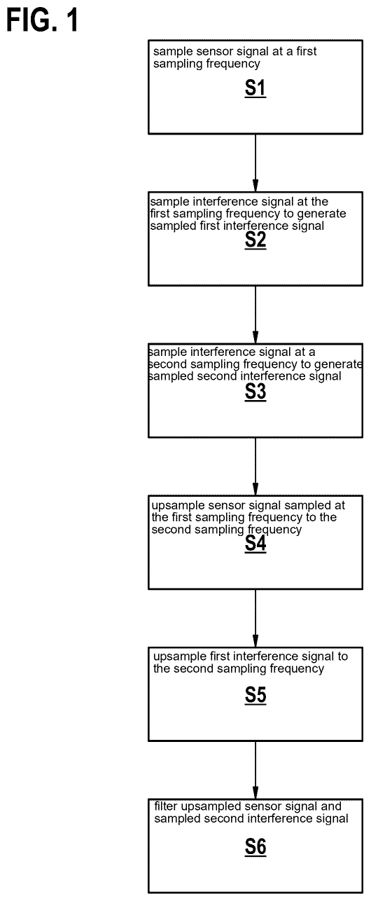

FIG. 1 is a schematic flow diagram of a possible embodiment of a method according to the present invention for compensating for an interference signal in a sensor 20, which can be integrated in an apparatus 100. The sensor 20 can be a MEMS sensor.

However, the method according to the present invention is not only suitable for micromechanical sensors, but for any sensors that provide a sensor output signal.

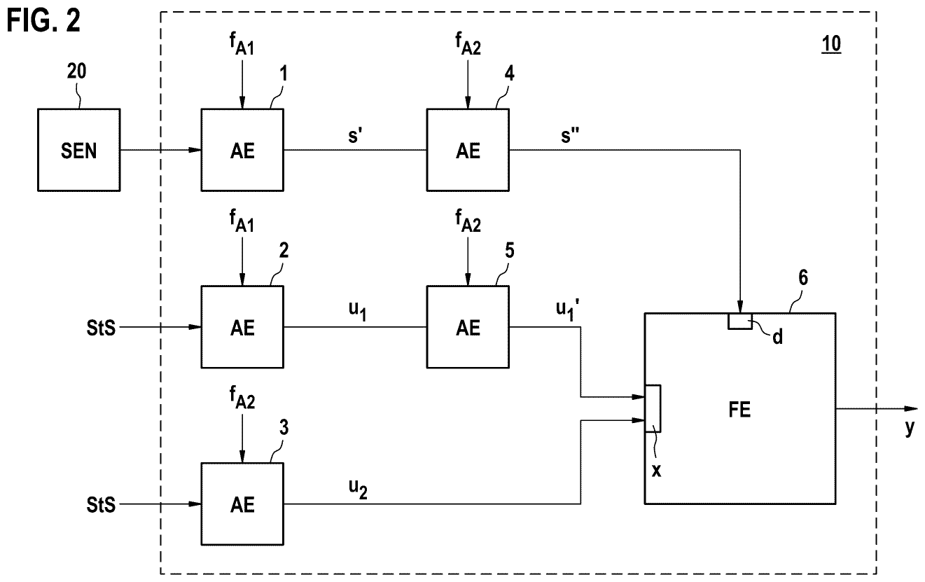

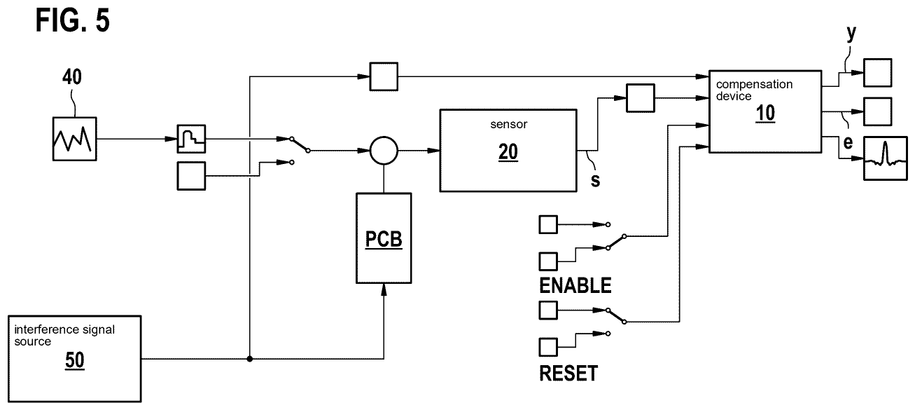

In one possible embodiment, the interference signal compensation is carried out by a compensation device 10 as shown in the block diagram according to FIG. 2 and in FIG. 5.

In the method according to the present invention, sampled interference signals can either be generated in advance and stored in a data memory DS, which provides these sampled interference signals to an adaptive filter 6, or alternatively can be generated during operation of the sensor 20 using sampling units.

FIG. 1 shows a flow chart showing an embodiment in which the sampled interference signals are generated by sampling units during operation of the sensor 20.

In one possible embodiment of the method according to the present invention for compensating for an interference signal in a sensor 20, the method comprises the following n steps.

In a first step S1, a sensor signal s received from a sensor 20 is sampled by a first sampling unit 1 of the device 10 at a first sampling frequency fA1 to generate a sampled sensor signal s′.

In a second step S2, the interference signal is sampled by a second sampling unit 2 of the device 10 at the first sampling frequency fA1 to generate a sampled first interference signal u1.

In one possible embodiment of the method according to the present invention, the first sampling frequency fA1 used in steps S1, S2 is more than twice the maximum frequency fmax of the sensor signal frequency bandwidth.

In a third step S3, the interference signal is sampled by a third sampling unit 3 of the device 10 at a second sampling frequency fA2 to generate a sampled second interference signal u2, wherein the second sampling frequency fA2 is higher than the first sampling frequency fa1.

In one possible embodiment of the method according to the present invention, the second sampling frequency fA2 used in step S3 is more than twice the maximum frequency fmax of the interference signal frequency bandwidth.

In a fourth step S4, a fourth sampling unit 4 upsamples the sensor signal s′ sampled at the first sampling frequency fA1 to the second sampling frequency fA2 to generate an upsampled sensor signal s″.

In a fifth step S5, a fifth sampling unit 5 of the device 10 upsamples the sampled first interference signal u1 to the second sampling frequency fA2 to generate an upsampled first interference signal u1′.

In a sixth step S6, the first interference signal u1′ upsampled to the second sampling frequency fA2 and the second interference signal u2 sampled at the second sampling frequency fA2 are filtered via an adaptive filter unit 6 of the device 10 to generate a filtered output signal y with a compensated interference signal, wherein the upsampled sensor signal s″ generated in the fourth step S4 is applied to a reference signal input d of the adaptive filter unit 6.

In this embodiment, the sampling units 2, 3, 5 of a provision unit of the compensation device 10, shown in FIG. 2, form a provision unit which, during operation of the sensor 20, provides the sampled interference signals and applies them to the input x of the filter unit 6.

Alternatively, the interference signals can be sampled beforehand (steps S2, S3, S5) and stored in a data memory DS. During operation of the sensor 20, the sampled interference signals stored in the data memory DS are read out and applied to the input x of the adaptive filter unit 6.

The above-mentioned steps S of the method sequence shown in FIG. 1 can be carried out partly in parallel and/or in a different order.

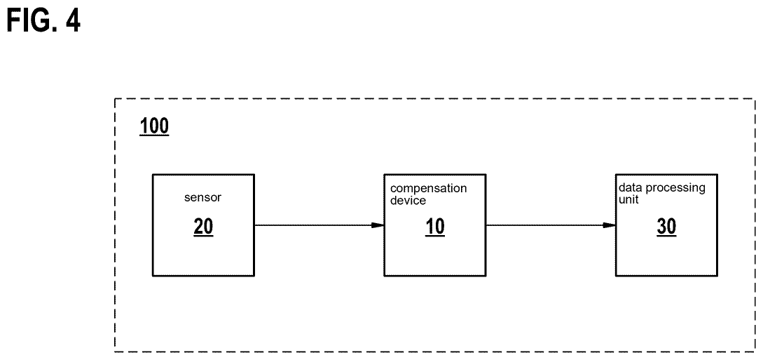

In one possible embodiment of the method according to the present invention for compensating for an interference signal, the sensor signal s is generated by a micromechanical sensor 20 of an apparatus 100, as shown schematically in FIG. 4.

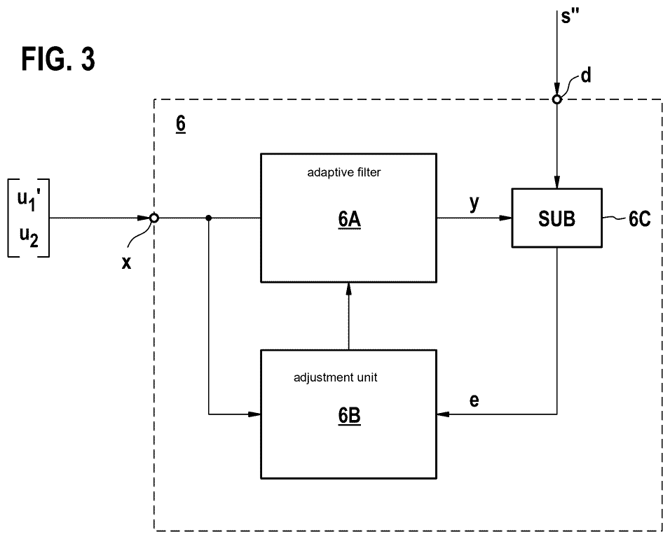

As shown in FIG. 3, in a possible embodiment of the method according to the present invention, the output signal y of the adaptive filter 6A of the filter unit 6 of the compensation device 10 is subtracted from a reference signal d to generate the error signal e. In one possible embodiment, the reference signal d for the filter unit 6 is formed by the upsampled sensor signal s″ generated by the fourth sampling unit 4.

In one possible embodiment of the method according to the present invention, the filter coefficients w of the adaptive filter 6A within the filter unit 6 are iteratively adjusted to minimize the error signal e.

In one possible embodiment of the according to the present invention, the filter coefficients w of the adaptive filter 6A are adjusted by an adjustment algorithm. In possible embodiments, the adjustment algorithm comprises an LMS algorithm, an RLS algorithm or an NLMS algorithm. The adjustment algorithm is preferably executed by an ASIC. Alternatively, the adjustment algorithm can also be executed by a processor.

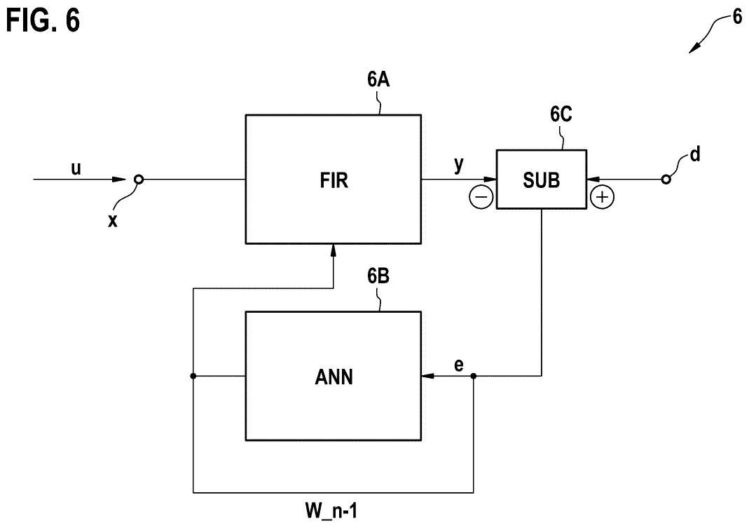

In an alternative embodiment of the according to the present invention, the filter coefficients w of the adaptive filter 6A of the filter unit 6 are adjusted by an artificial neural network ANN, as also shown in FIG. 6.

In one possible embodiment of the method according to the present invention, the interference signal is sampled at intermediate sampling frequencies to generate sampled further interference signals ui, wherein the further intermediate sampling frequencies lie between the first sampling frequency fA1 and the second sampling frequency fA2.

The further interference signals sampled at the intermediate sampling frequencies are filtered together with the first interference signal u1′ upsampled to the second sampling frequency fA2 and with the second interference signal u2 sampled at the second sampling frequency fA2, via an adaptive filter unit 6 of the compensation device 10, to generate a filtered output signal y with a compensated interference signal. The filtered output signal y of the filter unit 6 can be processed by a data processing unit 30 of the apparatus 100

According to a further aspect, the present invention provides a device 10 for compensating for an interference signal in a sensor 20 comprising a plurality of sampling units. In one possible embodiment of the device 10, the sampled interference signals are generated during operation by sampling units 2, 3, 5 of a provision unit, as shown in the block diagram according to FIG. 2.

Alternatively, the interference signals can also be sampled beforehand and stored in a data memory DS of the compensation device 10. During operation of the sensor 20, the data memory provides the sampled interference signals stored therein, which are applied to the input x of the adaptive filter unit 6.

The device 10 has a first sampling unit 1, in particular an analog-to-digital converter, which is designed to sample a sensor signal s received from the sensor 20 at a first sampling frequency fa1 to generate a sampled sensor signal s′.

In the embodiment shown in FIG. 2, the device 10 has a second sampling unit 2, in particular an analog-to-digital converter, which is designed to sample the interference signal at the first sampling frequency fA1 to generate a sampled first interference signal u1.

In the embodiment shown in FIG. 2, the device 10 has a third sampling unit 3, in particular an analog-to-digital converter, which is designed to sample the interference signal at a second sampling frequency fA2 to generate a sampled second interference signal u2, wherein the second sampling frequency fA2 is higher than the first sampling frequency fA1.

The sampling frequencies fA1, fA2 are adjustable in a possible implementation for the relevant application and sensor 20.

In the embodiment shown in FIG. 2, the device 10 has a fourth sampling unit 4 which is designed to upsample the sensor signal s′ sampled at the first sampling frequency fA1 to the second sampling frequency fA2, wherein an upsampled sensor signal s″ is generated.

In the embodiment shown in FIG. 2, the device 10 further comprises a fifth sampling unit 5 which is designed to upsample the sampled first interference signal u1 to the second sampling frequency fA2, wherein an upsampled first interference signal u1′ is generated.

The device 10 further comprises an adaptive filter unit 6 which filters the first interference signal u1′ upsampled to the second sampling frequency fA2 and the second interference signal u2 sampled at the second sampling frequency fA2 to generate a filtered output signal y with a compensated interference signal.

In one possible embodiment of the device 10 for compensating for an interference signal in a sensor 20, the filter unit 6 contains an adaptive filter 6A with filter coefficients w, which can be iteratively adjusted by an adjustment unit 6B of the filter unit 6 to minimize an error signal e.

In one possible embodiment of the device 10, the adjustment unit 6B of the filter unit 6 executes an adjustment algorithm, in particular an LMS algorithm, an RLS algorithm or an NLMS algorithm.

In an alternative embodiment of the device 10, the adjustment unit 6B of the filter unit 6 comprises an artificial neural network ANN, in particular a recursive neural network RNN, as shown in FIG. 6.

There are various variants for its implementation within the compensation device 10.
ANN->as input u, e, W_n->W_n
ANN->as input u, y, d, W_n->W_n
RNN->as input u, y->W_n
RNN->as input u, y, d->W_n
W_n=ANN (u, e, W_n−1)
W_n=ANN (u, y, d, W_n−1)
W_n=RNN (u, e)
W_n=RNN (u, y, d)

A direct estimation or prediction of the error e and the output signal y can also be performed.
[y, e]=ANN (u, d)
   where the ANN is preferably formed by a CNN (Convolutional Neural Network).

Alternatively, a recursive neural network RNN can also be used for the direct estimation of the error e and the output signal y:
[y, e]=RNN (u, d)

In one possible embodiment of the device 10 for compensating for an interference signal in a sensor, the device 10 contains a subtraction unit 6C, as shown in FIG. 3, which subtracts the output signal y of the adaptive filter 6A of the filter unit 6 from a reference signal applied to a reference signal input d of the filter unit 6 to generate the error signal e. In this case, the reference signal is preferably formed by the sensor signal s″ upsampled by the fourth sampling unit 4 of the device 10.

In one possible embodiment of the device 10 for compensating for an interference signal in a sensor 20, the sensor 20 comprises a micromechanical sensor. The micromechanical sensor 20 comprises, for example, a rotation rate sensor, an acceleration sensor and/or a pressure sensor. In one possible embodiment of the device 10 for compensating for an interference signal in a sensor 20, the signal comprises a vibration disturbance, as shown in FIG. 5.

In one possible embodiment, the device 10 is integrated in a sensor housing of the sensor 20.

FIG. 5 shows a setup with a signal source 40 that provides a signal that is superimposed by an interference signal. In the example shown in FIG. 5, the interference signal originates from a printed circuit board (PCB) which is set into vibration by a vibration signal originating from an interference signal source 50. The measurement signal and the added interference signal are applied as the input signal to the sensor 20, which generates a sensor output signal s. The sensor output signal s is fed to the compensation device 10, as shown in FIG. 5.

A basic idea of the method according to the present invention is to provide the adaptive filter of the device 10 with the necessary signals u for reconstructing the desired signal d. Applied to the LMS algorithm—but any other adaptive filter algorithm can also be used—this means that the sampled interference signal u1, u2 is provided to the adaptive filter unit 6 as a further input signal:

$$y = {W}_{n - 1}^{T} [ {u}_{1} {u}_{2} ] \qquad ( 1 )$$

here, y represents the filtered output signal of the adaptive filter. Wₙ₋₁^{T} is the transposed weight vector at time n−1, and [u1, u2] is the input vector at the signal input x of the filter unit 6.

$$e = d - sum ( diag ( y ) ) \qquad ( 2 )$$

Here, e represents the error between the desired output d and the estimated output y. The term sum (diag(y)) sums up the diagonal elements of y.

$${W}_{n} = α {W}_{n - 1} + f ( e , [ {u}_{1} {u}_{2} ] , μ ) , \qquad ( 3 )$$

Wn represents the weightings (or coefficients) of the adaptive filter at a certain time n.

Wn−1 represents the previous state of the weightings w, i.e., the weightings w at time n−1.

α: This is a factor that controls the adjustment of the weightings w. It is multiplied by the previous weightings. f(e, [u1, u2], μ) is a function that uses the error e and a vector of input signals [u1, u2] to adjust the weightings or filter coefficients w of the adaptive filter 6A of the filter unit 6, where μ represents the learning rate or the step size.

In one possible embodiment, the step size of the adaptive filter is adaptively changed.

In one possible embodiment, the update function is linearly separable. This results in:

$${W}_{n}^{1} = α {W}_{n - 1}^{1} + f ( e , {u}_{1} , μ )$$

$${W}_{n}^{2} = α {W}_{n - 1}^{2} + f ( e , {u}_{2} , μ )$$

where the 1 at W¹ₙ means that this only includes the weights for u₁ and 2 . . . n according to a comparable model.

In an alternative embodiment, the update function is not linearly separable. In a possible implementation using a normalized LMS algorithm, the update can be defined as follows:

$${W}_{n} = α {W}_{n - 1} + μ e \frac{{[ {u}_{1} {u}_{2} ]}^{*}}{∖ eps + {[ {u}_{1} {u}_{2} ]}^{H} [ {u}_{1} {u}_{2} ]}$$

An update can also be performed across multiple signals in a batch:

$${W}_{n} = α {W}_{n - 1} + 1 / N {\sum }_{i}^{N} f ( e , [ {u}_{1}^{i} {u}_{2}^{i} ] , μ ) ,$$

The above equation (3) describes a recursive process in which the weightings Wn are adjusted based on the previous weightings Wn−1 and a filter function f. The factor α influences the extent to which the previous weightings are included in the calculation.

The sequences u1′, u2 arriving at the input x of the filter unit 6 pass through the adjustable transversal filter 6A of the filter unit 6 and form the output sequence y(n). This sequence y(n) is compared with the sequence d(n) to be formed by the filter and provides the error signal e(n). In the ideal case, i.e., when the filter changes the input sequence u(n) by filtering exactly such that the output sequence y(n) becomes equal to the reference sequence d(n), the error sequence is e(n)=0. In the case of a deviation, the error signal e(n) has values other than 0. The closed-loop control algorithm or adjustment algorithm of the filter unit 6 attempts to minimize the error signal e by changing the filter coefficients w of the transversal filter 6A, i.e., to adapt the output sequence y of the filter to the reference signal d(n) as well as possible.

In one possible embodiment, the sequences u1′, u2 arriving at the input x of the filter unit 6 can also be read out from a data memory DS. The signal sequences u1′, u2 contain data or samples. The signal sequences applied to the input x of the filter unit 6 may also include known test signal sequences.

Alternatively, the sequences u1′, u2 arriving at the input x of the filter unit 6 can also be generated by the sampling units 2, 3, 5 shown in FIG. 2 during the operation of the sensor 20.

In this case, in a possible embodiment, the adjustment algorithm is based on a method for minimizing the square errors, the LMS algorithm. Better results can be achieved in one possible embodiment with a somewhat more complex, recursive method such as the RLS (Recursive-Least-Squares) algorithm.

The adaptive filter 6A of the closed-loop filter unit 6 uses feedback in the form of the error signal e to refine its transfer function.

In general, the closed-loop adaptive process involves using a cost function, which is a criterion for the optimal performance of the filter, to feed an algorithm that determines how to modify the filter transfer function to minimize the cost in the next iteration. The cost function in one possible implementation is the mean square of the error signal e. The idea behind a closed-loop adaptive filter is that the variable filter is adjusted until the error e, i.e., the difference between the filter output y and the desired signal d, is minimized.

Different types of adaptive filters can be used in the compensation device 10 according to the present invention, which have specific properties depending on the field of application and requirements.

LMS (Least Mean Squares) filter: The LMS algorithm is one of the easiest adaptive algorithms to implement. It minimizes the mean square error between the estimated and the actual signal. LMS filters are lightweight and well suited for real-time applications.

NLMS (Normalized Least Mean Squares) filter: This is an improved version of the LMS algorithm where the step size (learning rate) is normalized based on the power of the input signal. This helps to improve the convergence speed.

RLS (Recursive Least Squares) filters: In contrast to LMS filters and NLMS filters, which perform a step-by-step adjustment, the RLS algorithm uses a recursive calculation of the filter coefficients. This can lead to faster convergence, but is more computationally complex.

Kalman filters: Kalman filters are typically designed for estimating system states in dynamic systems.

FIR (Finite Impulse Response) and IIR (Infinite Impulse Response) filters (preferably a Kalman filter is used here, according to the present invention): Both FIR and IIR filters can be adaptive. FIR filters have a finite impulse response, while IIR filters have an infinite impulse response. Adaptivity can be achieved by adjusting the coefficients w in both filter types.

The step size (also called learning rate) is an important parameter in adaptive filters that specifies how much the coefficients of the filter should be adjusted at each iteration. The step size influences the convergence speed and stability of the adaptive filter.

A larger step size leads to faster adjustments of the coefficients, which can accelerate the convergence. However, a step size that is too large can lead to oscillations or divergence, which may cause the adaptive filter to fail to converge or the coefficients to fluctuate uncontrollably.

A smaller step size results in slower adjustments, which can improve stability. However, a step size that is too small can lead to slow convergence or insufficient adaptation to changes in the input signal.

The selection of the optimal step size depends on various factors, including the characteristics of the input signal, the dynamics of the system, and the convergence requirements of the application. In one possible embodiment, the step size is adjusted during the adaptation process to ensure balanced performance.

The LMS (Least Mean Squares) algorithm and its variants, such as the NLMS (Normalized LMS) algorithm, use the step size as an important parameter.

The term “leakage factor” is often used in connection with adaptive filters, especially in the case of LMS (Least Mean Squares) or NLMS (Normalized LMS) algorithms. The leakage factor plays a role in adjusting the coefficients in a filter, and it affects the convergence speed and stability of the adaptive filter.

The leakage factor refers to how much of the previous adjustment is retained in the current coefficient w. A leakage factor of less than one causes the coefficients w to be more easily forgotten or attenuated, which can cause the adaptive filter to respond more quickly to changes in the input signal. On the other hand, a leakage factor close to one may lead to a greater consideration of past adjustments, resulting in a stable but slower response to changes.

Further embodiments of the method according to the present invention and the device according to the present invention are possible.

In one possible embodiment of the method according to the present invention, a calculation is carried out with an adaptive filter using the undersampled signals without upsampling.

In another possible embodiment of the method according to the present invention, different weightings of the mixed terms sum(diag(y)) are formed with an arbitrary function that maps the signal y\elem R\hat{ }(n,m) to R\hat{ }(1,1).

In one possible embodiment of the method according to the present invention, an estimation of the filter is carried out instead of the inverse filter. This can be achieved by swapping the signal inputs x and d on the filter unit 6.

In a further possible embodiment of the method according to the present invention, the adaptive filter is extended by an internal sampling of the signal y.

In one possible embodiment of the method according to the present invention, a nonlinear filter path is used for the signal and interference signal.

Particularly advantageous is the implementation by applying a polynomial function, e.g., a quadratic or cubic function, to the measured interference signals u1, u1′, u2.

In the case of nonlinear compensation, in one possible embodiment only the second interference signal u2 sampled at the second sampling frequency fA2 is provided with the modulation, while the first interference signal u1 is given a weighting of zero or sampling or reading of the first interference signal u1 is not implemented.

In a further possible embodiment of the method according to the present invention, a time-variant filter path is used for the signal and the interference signal.

Particularly advantageous is the implementation by multiplying the interference signals—u1, u1′, u2 and higher—with sin and cos functions of different frequencies, before they pass through the FIR filter.

In one possible embodiment of the method according to the present invention, the interference signal is compensated for by means of a nonlinear and/or time-variant convolution. Conceptually, this is similar to the compensation of the by means of the sampled interference signals u_1 . . . u_i, although the sampled interference signals u_1 . . . u_i can contain different multiplications with different frequencies. Furthermore, the different approaches can be combined, e.g., in the form u_1 . . . u_i, u_i+1 . . . u_m.

In a further possible embodiment of the method according to the present invention, a non-continuous compensation is carried out, e.g., by determination, if no external measuring signal is present.

In the method according to the present invention, the interference signal StS and its signal path are approximated by the various interference signals u, which arise, for example, through undersampling, convolution, etc.—including the FIR filters.

What is claimed is:

1. A method for compensating for an interference signal in a sensor, comprising the following steps:
sampling a sensor signal received from the sensor at a first sampling frequency to generate a sampled sensor signal;
(i) providing a sampled first interference signal, the interference signal having been sampled at the first sampling frequency and then upsampled to a second sampling frequency, wherein the second sampling frequency is higher than the first sampling frequency, and/or (ii) providing a sampled second interference signal, the interference signal having been sampled at the second sampling frequency;
upsampling the sensor signal sampled at the first sampling frequency to the second sampling frequency to generate an upsampled sensor signal;
filtering the provided sampled first interference signals and/or the provide sampled second interference signal via an adaptive filter unit to generate a filtered output signal with a compensated interference signal, wherein the upsampled sensor signal is applied as a reference signal to a reference signal input of the adaptive filter unit.

2. The method according to claim 1, wherein the sensor signal is generated by a micromechanical sensor.

3. The method according to claim 1, wherein the output signal of the adaptive filter is subtracted from the reference signal to generate an error signal.

4. The method according to claim 1, wherein the provided sampled first interference signal and/or the provided sampled second interference signal are read out from a data memory.

5. The method according to claim 3, wherein filter coefficients of the adaptive filter are iteratively adjusted to minimize the error signal.

6. The method according to claim 5, wherein the filter coefficients of the adaptive filter are adjusted by an adjustment algorithm.

7. The method according to claim 6, wherein the adjustment algorithm includes an LMS algorithm or an RLS algorithm or an NLMS algorithm.

8. The method according to claim 5, wherein the filter coefficients of the adaptive filter are adjusted by an artificial neural network (ANN).

9. The method according to claim 1, wherein the second sampling frequency is more than twice a maximum frequency of a interference signal frequency bandwidth of the interference signal.

10. The method according to claim 1, wherein the first sampling frequency is more than twice a maximum frequency of a sensor signal frequency bandwidth of the sensor signal.

11. The method according to claim 1, wherein the interference signal is sampled at intermediate sampling frequencies to generate sampled further interference signals, wherein the further intermediate sampling frequencies lie between the first sampling frequency and the second sampling frequency.

12. The method according to claim 11, wherein the further interference signals sampled at the intermediate sampling frequencies are filtered together with the first interference signal upsampled to the second sampling frequency and with the second interference signal sampled at the second sampling frequency, via an adaptive filter, to generate a filtered output signal with a compensated interference signal.

13. The method according to claim 1, wherein the interference signal is compensated for using a nonlinear and/or time-variant convolution.

14. A device for compensating for an interference signal in a sensor, comprising:
a sampling unit configured to sample a sensor signal received from the sensor at a first sampling frequency to generate a sampled sensor signal;
a provision unit with sampling units configured to: provide a first sampled interference signal, the interference signal having been sampled at the first sampling frequency and then upsampled to a second sampling frequency, wherein the second sampling frequency is higher than the first sampling frequency, and/or provide a sampled second interference signal, the interference signal having to be sampled at the second higher sampling frequency;
a further sampling unit configured to upsample the sensor signal sampled at the first sampling frequency to the second sampling frequency to generate an upsampled sensor signal; and
an adaptive filter unit configured to filter the provided first interference signal upsampled to the second sampling frequency and/or the provided second interference signal sampled at the second sampling frequency, to generate a filtered output signal with a compensated interference signal, wherein the sensor signal upsampled by the further sampling unit is applied as a reference signal to a reference signal input of the adaptive filter unit of the device.

15. The device according to claim 14, wherein the provision unit includes sampling units for providing the first sampled interference signal and/or the sampled second interference signal:
a second sampling unit configured to sample the interference signal at the first sampling frequency to generate the sampled first interference signal;
a third sampling unit configured to sample the interference signal at the second sampling frequency to generate the sampled second interference signal; and
a fifth sampling unit configured to upsample the sampled first interference signal to the second sampling frequency.

16. The device according to claim 14, wherein the provision unit configured to provide the first sampled interference signal and/or the sampled second interference signal has a data memory in which the first sampled interference signal and/or the sampled second interference signal are stored.

17. The device according to claim 14, wherein the adaptive filter unit includes an adaptive filter with filter coefficients which can be adjusted iteratively by an adjustment unit of the filter unit to minimize an error signal.

18. The device according to claim 17, wherein the adjustment unit of the filter unit executes an adjustment algorithm including: an LMS algorithm or an RLS algorithm or an NLMS algorithm.

19. The device according to claim 17, wherein the adjustment unit of the filter unit includes an artificial neural network (ANN).

20. The device according to claim 14, further comprising:
a subtraction unit which subtracts the output signal of the adaptive filter from a reference signal applied to the reference signal input of the filter unit to generate the error signal, wherein the applied reference signal is formed by the upsampled sensor signal.

21. The device according to claim 14, wherein the sensor includes a micromechanical sensor.

22. The device according to claim 21, wherein the micromechanical sensor includes includes a rotation rate sensor and/or an acceleration sensor and/or a pressure sensor.

23. The device according to claim 14, wherein the interference signal comprises a vibration disturbance.

24. An apparatus, comprising:
at least one sensor; and
a compensation device for compensating for an interference signal in the sensor, the compensation device including:
a sampling unit configured to sample a sensor signal received from the sensor at a first sampling frequency to generate a sampled sensor signal,
a provision unit with sampling units configured to: provide a first sampled interference signal, the interference signal having been sampled at the first sampling frequency and then upsampled to a second sampling frequency, wherein the second sampling frequency is higher than the first sampling frequency, and/or provide a sampled second interference signal, the interference signal having to be sampled at the second higher sampling frequency,
a further sampling unit configured to upsample the sensor signal sampled at the first sampling frequency to the second sampling frequency to generate an upsampled sensor signal, and
an adaptive filter unit configured to filter the provided first interference signal upsampled to the second sampling frequency and/or the provided second interference signal sampled at the second sampling frequency, to generate a filtered output signal with a compensated interference signal, wherein the sensor signal upsampled by the further sampling unit is applied as a reference signal to a reference signal input of the adaptive filter unit of the device.
